(19) United States
(12) Patent Application Publication
(10) Pub. No.: US 2014/0299893 A1
(43) Pub. Date: Oct. 9, 2014

(54) Conductive Connector For Use With Circuit Board, and LED Module Having the Same

(71) Applicant: JOINT TECH ELECTRONIC INDUSTRIAL CO., LTD., (US)

(72) Inventor: Chih-Sheng WENG, Taipei City (TW)

(73) Assignee: JOINT TECH ELECTRONIC INDUSTRIAL CO., LTD., New Taipei City (TW)

(21) Appl. No.: 13/857,798

(22) Filed: Apr. 5, 2013

(51) Int. Cl. H01R 12/71; H01L 33/62

(52) U.S. Cl. CPC H01R 12/71; H01L 33/62
USPC 257/88; 439/81

(57) ABSTRACT

A conductive connector for use with circuit boards is characterized in that a conductive connection plug and a conductive connection socket are disposed on two circuit boards, respectively. The conductive connection plug has an inserting portion protruding from the edge of the first circuit board. The conductive connection socket has a clamping portion for clamping and securing the inserting portion of the conductive connection plug. The conductive connection plug is plugged into the conductive connection socket to enable the two circuit boards to be put together easily and quickly and reduce required space. An LED module is characterized in that the conductive connector connects circuit boards each having at least one LED component to enable the circuit boards to be put together easily and quickly, taken apart easily, and changed easily.

### FIELD OF THE INVENTION

The present invention relates to conductive connectors, and more particularly, to a contact that enables electrical connection of two circuit boards and electrical conduction between the two circuit boards.

### BACKGROUND OF THE INVENTION

It is not uncommon for a plurality of circuit boards to be installed inside electric appliances and electronic devices to increase the area available for expansion of circuits and the mounting of electronic components. Alternatively, a plurality of modularized circuit boards features enhancement of performance. For example, an LED module comprises a circuit board as well as an LED component and a driving circuit which are mounted on the circuit board, such that the circuit boards of the plurality of LED modules are connected in order to provide sufficient brightness of illumination.

According to an instance of the prior art, the connection between circuit boards is achieved by soldering a wire to the contacts on the circuit boards. However, the prior art has drawbacks. Wires of an appropriate length have to be manually soldered to the contacts on the circuit boards. If the contacts and a driving circuit mounted on the circuit boards are intricate and sophisticated, the aforesaid manual soldering process will be difficult to carry out, thereby compromising the manufacturing process and the quality thereof. Furthermore, to change one of the circuit boards, it is necessary to unsolder the wires connecting the contacts on the circuit boards, and it is inconvenient to do so.

According to another instance of the prior art, the connection between circuit boards 10, 20 is effectuated by a straddling device 30. Referring to FIG. 1, the straddling device 30 comprises a carrying base 31, a straddling block 32, two connection terminals 33a, 33b and a fixing element 34. The straddling block 32 is mounted on the carrying base 31 by means of the fixing element 34. The two connection terminals 33a, 33b are disposed below the straddling block 32. The connection terminals 33a connect a contact 11a of the circuit board 10 and a contact 21a of the circuit board 20, whereas the connection terminals 33b connect a contact 11b of the circuit board 10 and a contact 21b of the circuit board 20, such that the two circuit boards 10, 20 are electrically connected. However, the straddling device 30 consists of so many components as to hinder miniaturization and prevent material cost reduction.

### SUMMARY OF THE INVENTION

In view of the aforesaid drawbacks of the prior art, it is an objective of the present invention to provide a conductive connector for use with circuit boards, characterized in that two circuit boards are connected by a conductive connection plug and a conductive connection socket corresponding in position thereto, to thereby render assembly convenient and quick, reduce required space, and cut material costs.

In order to achieve the above and other objectives, the present invention provides a conductive connector adapted for use with circuit boards and adapted to electrically connect and series-connect a first circuit board and a second circuit board, the first circuit board having a first positioning point, and the second circuit board having a second positioning point, the conductive connector comprising: a conductive connection plug having a first positioning portion, a first abutting portion, and an inserting portion, the first positioning portion being positioned at the first positioning point of the first circuit board, the first abutting portion being disposed at a bottom of the conductive connection plug and soldered to the first circuit board to abut thereon, wherein, as soon as the conductive connection plug is mounted on the first circuit board, the inserting portion protrudes from the first circuit board; and a conductive connection socket having a second positioning portion, a second abutting portion, and a clamping portion, the second positioning portion being positioned at the second positioning point of the second circuit board, the second abutting portion being disposed at a bottom of the conductive connection socket and soldered to the second circuit board to abut thereon, wherein, as soon as the conductive connection socket is mounted on the second circuit board, the clamping portion is positioned proximate to an edge of the second circuit board to thereby clamp the inserting portion of the conductive connection plug.

In an embodiment, the inserting portion of the conductive connection plug comprises an inserting plate and an engaging block protruding from a surface of the inserting plate, and the clamping portion of the conductive connection socket comprises a resilient clamping element, a stopping element, and an engaging hole disposed on the stopping element and corresponding in position to the engaging block, such that the resilient clamping element and the stopping element have therebetween a gap for admitting the inserting plate.

In an embodiment, the conductive connection socket further comprises two lateral baffling plates between which the clamping portion is disposed.

In an embodiment, the conductive connection plug has a first flat top connected to the inserting plate extending downward, the conductive connection socket has a second flat top connected to the resilient clamping element extending downward, and the stopping element connects to the second abutting portion and extends upward.

In an embodiment, as soon as the conductive connection plug is plugged into the conductive connection socket, the first flat top of the conductive connection plug and the second flat top of the conductive connection socket are coplanar.

In order to achieve the above and other objectives, the present invention further provides an LED module comprising the conductive connector, a first circuit board having thereon at least one LED component, and a second circuit hoard having thereon at least one LED component.

Hence, according to the present invention, a conductive connector for use with circuit boards is characterized in that two circuit hoards are connected by a conductive connection plug and a conductive connection socket which are disposed on the two circuit boards, respectively, and operate in conjunction with each other, such that the conductive connection plug can be plugged into the conductive connection socket to thereby render assembly of the two circuit boards convenient and quick, and reduce required space. Furthermore, the conductive connector is simple in structure to thereby reduce the required use of materials and cut assembly costs. Furthermore, the present invention further provides an LED module characterized in that circuit boards each having thereon at least one LED component are connected by means of a conductive connector, such that it is convenient and quick to put together the circuit boards and thereby render it easy to take apart the circuit boards and change a damaged one of the circuit boards.

### BRIEF DESCRIPTION OF THE DRAWINGS

Objectives, features, and advantages of the present invention are hereunder illustrated with specific embodiments in conjunction with the accompanying drawings, in which:

FIG. 1 (PRIOR ART) is a schematic view of a straddling device;

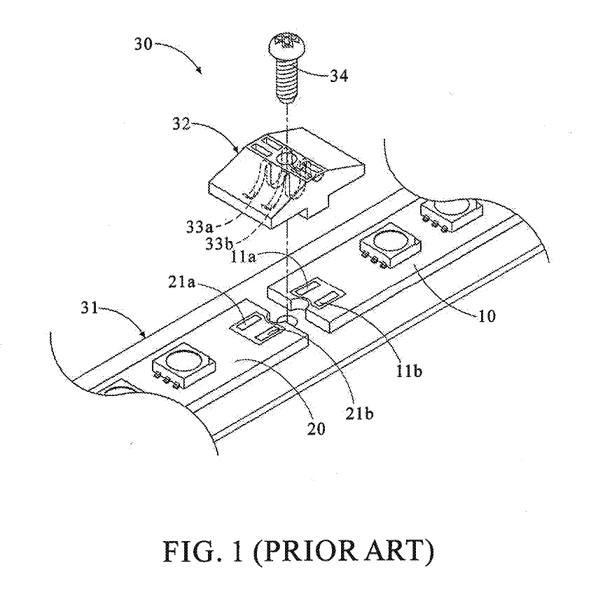

FIG. 2 is a schematic perspective view of a conductive connector according to the first embodiment of the present invention;

FIG. 3 is another schematic perspective view of the conductive connector according to the first embodiment of the present invention;

FIG. 4 is a schematic perspective view of the conductive connector when put together according to the first embodiment of the present invention;

FIG. 5 is a schematic cross-sectional view of two circuit boards having the conductive connector and being put together according to the first embodiment of the present invention;

FIG. 6 is a schematic cross-sectional view of the two circuit boards having the conductive connector and put together according to the first embodiment of the present invention; and

FIG. 7 is a schematic perspective view of an LED module according to the second embodiment of the present invention.

### DETAILED DESCRIPTION OF THE PREFERRED EMBODIMENTS

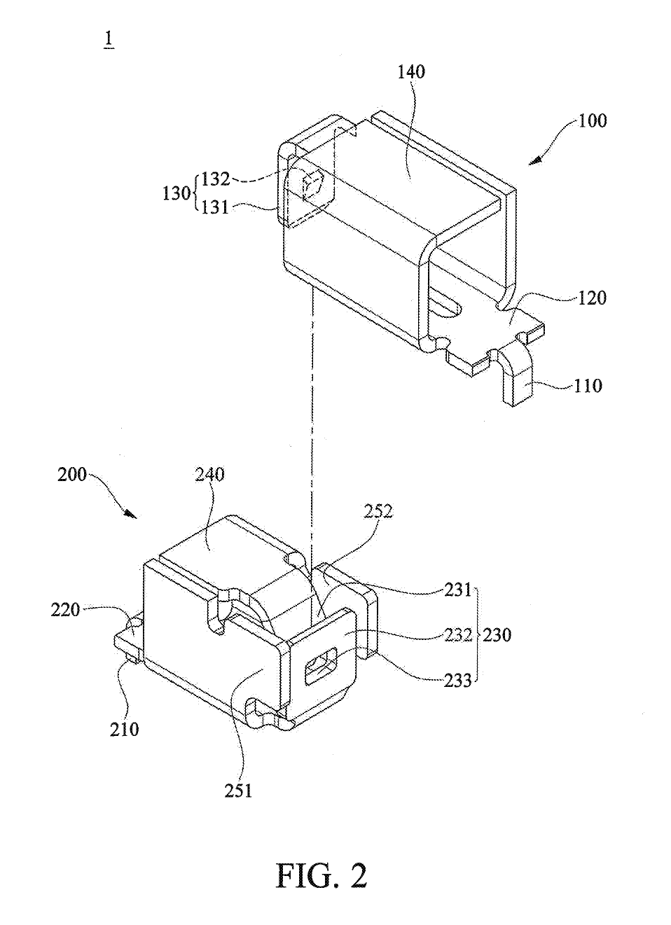

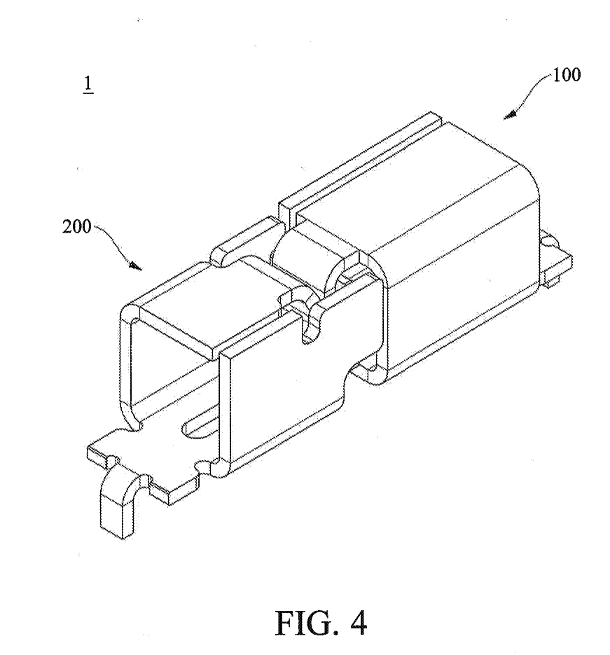

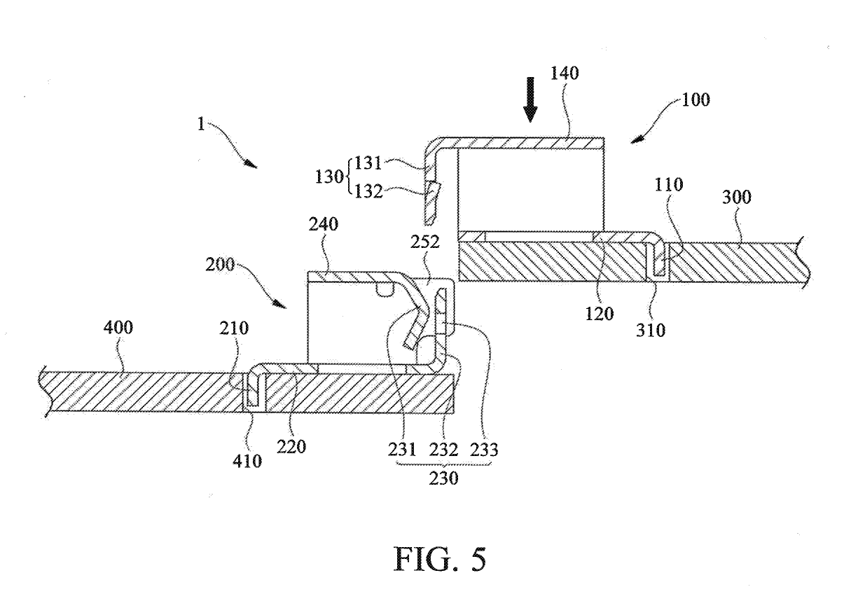

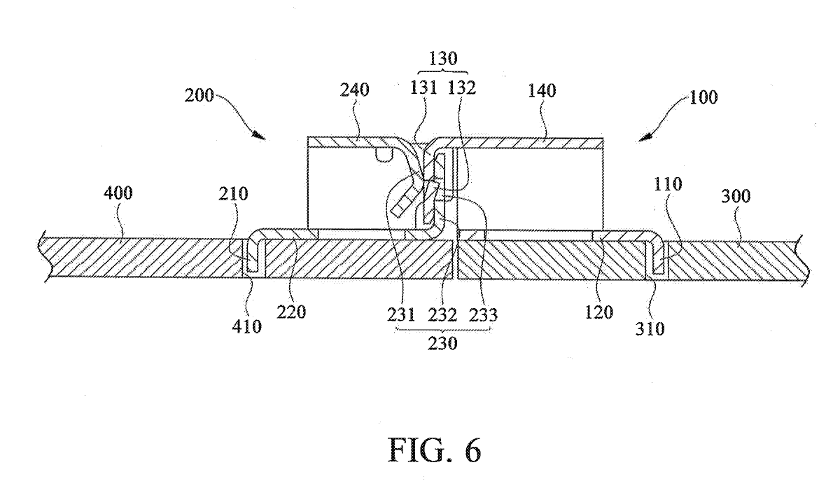

Referring to FIG. 2 through FIG. 6, there are shown schematic views of the first embodiment of the present invention. In the first embodiment of the present invention, a conductive connector 1 for use with circuit boards essentially comprises a conductive connection plug 100 and a conductive connection socket 200. Referring to FIG. 5 and FIG. 6, the conductive connector 1 is for use in electrically connecting and series-connecting a first circuit board 300 and a second circuit board 400. The first circuit board 300 has a first positioning point 310. The second circuit board 400 has a second positioning point 410. Preferably, the first positioning point 310 is positioned proximate to an edge of the first circuit board 300, whereas the second positioning point 410 is positioned proximate to an edge of the second circuit board 400.

Referring to FIG. 2 through FIG. 6, the conductive connection plug 100 has a first positioning portion 110, a first abutting portion 120 and an inserting portion 130. The first positioning portion 110 can be positioned at the first positioning point 310 of the first circuit board 300. The first abutting portion 120 is disposed at the bottom of the conductive connection plug 100 and soldered to the first circuit board 300 and thus abutting thereon. As soon as the conductive connection plug 100 is mounted on the first circuit board 300, the inserting portion 130 protrudes from the first circuit board 300. The conductive connection socket 200 has a second positioning portion 210, a second abutting portion 220 and a clamping portion 230. The second positioning portion 210 can be positioned at the second positioning point 410 of the second circuit board 400. The second abutting portion 220 is disposed at the bottom of the conductive connection socket 200 and soldered to the second circuit board 400 and thus abutting thereon, such that the conductive connection socket 200 is in contact with and electrically connected to the second circuit board 400. As soon as the conductive connection socket 200 is mounted on the second circuit board 400, the clamping portion 230 is positioned proximate to an edge of the second circuit board 400 to thereby clamp the inserting portion 130 of the conductive connection plug 100.

Accordingly, the conductive connector 1 in the first embodiment of the present invention is characterized in that the conductive connection plug 100 and the conductive connection socket 200 which are designed to operate in conjunction with each other are mounted on the first circuit board 300 and the second circuit board 400, respectively, such that the conductive connection plug 100 can be plugged into the conductive connection socket 200 to thereby put together and connect electrically the first circuit board 300 and the second circuit board 400 conveniently and quickly.

In the first embodiment of the present invention, the inserting portion 130 of the conductive connection plug 100 comprises an inserting plate 131 and an engaging block 132. The engaging block 132 protrudes from one surface of the inserting plate 131. The clamping portion 230 of the conductive connection socket 200 comprises a resilient clamping element 231, a stopping element 232 and an engaging hole 233. The engaging hole 233 is disposed on the stopping element 232 and corresponds in position to the engaging block 132. The resilient clamping element 231 and the stopping element 232 have therebetween a gap for admitting the inserting plate 131.

Referring to FIG. 5 and FIG. 6, the resilient clamping element 231 is a plate which bends toward the stopping element 232. The distance between the resilient clamping element 231 and the stopping element 232 is slightly less than the thickness of the inserting plate 131. Referring to FIG. 5, as soon as the inserting plate 131 of the conductive connection plug 100 is inserted into the gap between the resilient clamping element 231 and the stopping element 232, the resilient clamping element 231 deforms slightly to widen the gap, thereby allowing the inserting plate 131 to move downward and pass through the gap. Referring to FIG. 6, as soon as the engaging block 132 of the conductive connection plug 100 is engaged with the engaging hole 233 of the conductive connection socket 200, the resilient clamping element 231 and the stopping element 232 together clamp the inserting plate 131, such that the conductive connection plug 100 and the conductive connection socket 200 are coupled together firmly.

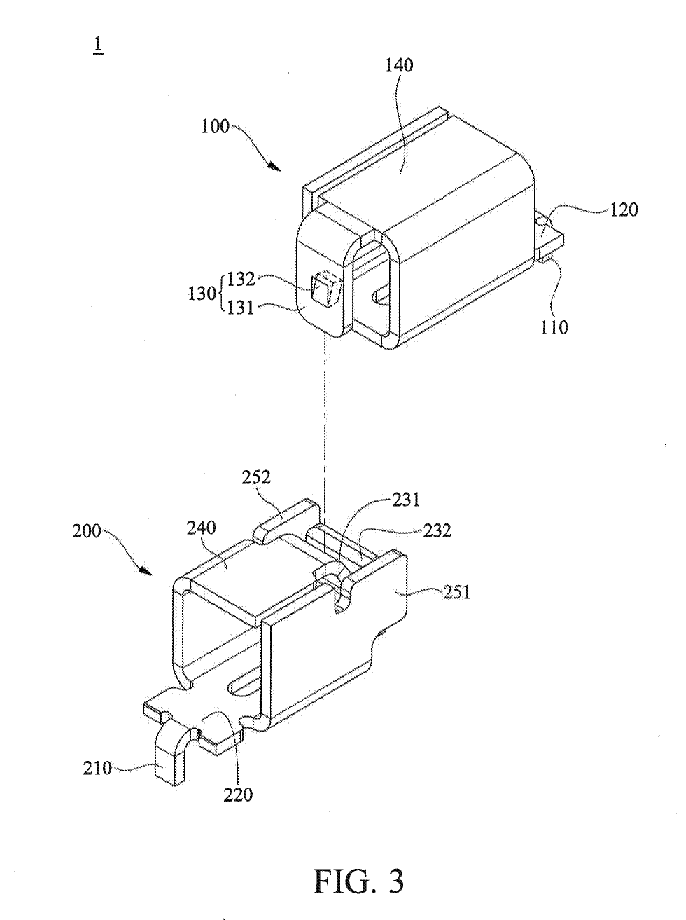

In the first embodiment of the present invention, referring to FIG. 2 and FIG. 3, the conductive connection socket 200 further comprises two lateral baffling plates 251, 252. The clamping portion 230 is disposed between the two lateral baffling plates 251, 252. As soon as the conductive connection plug 100 and the conductive connection socket 200 are put together, the inserting portion 130 of the conductive connection plug 100 is received in a space defined by the clamping portion 230 and the two lateral baffling plates 251, 252 of the conductive connection socket 200, thereby preventing the first circuit board 300 and the second circuit board 400 from sliding relative to each other laterally (i.e., in the direction parallel to the two opposing sides of the first circuit board 300 and the second circuit board 400).

In the first embodiment of the present invention, the conductive connection plug 100 has a first flat top 140 connected to the inserting plate 131 extending downward. The conductive connection socket 200 has a second flat top 240 connected to the resilient clamping element 231 extending downward. The stopping element 232 connects to the second abutting portion 220 and extends upward. Preferably, as soon as the conductive connection plug 100 is plugged into the conductive connection socket 200, the first flat top 140 of the conductive connection plug 100 and the second flat top 240 of the conductive connection socket 200 are coplanar. Both the conductive connection plug 100 and the conductive connection socket 200 are made of electrically conductive metal. The process of putting together the first circuit board 300 and the second circuit board 400 can be readily automated, because any mechanical arm is able to suck and fetch the first flat top 140 of the conductive connection plug 100 and the second flat top 240 of the conductive connection socket 200.

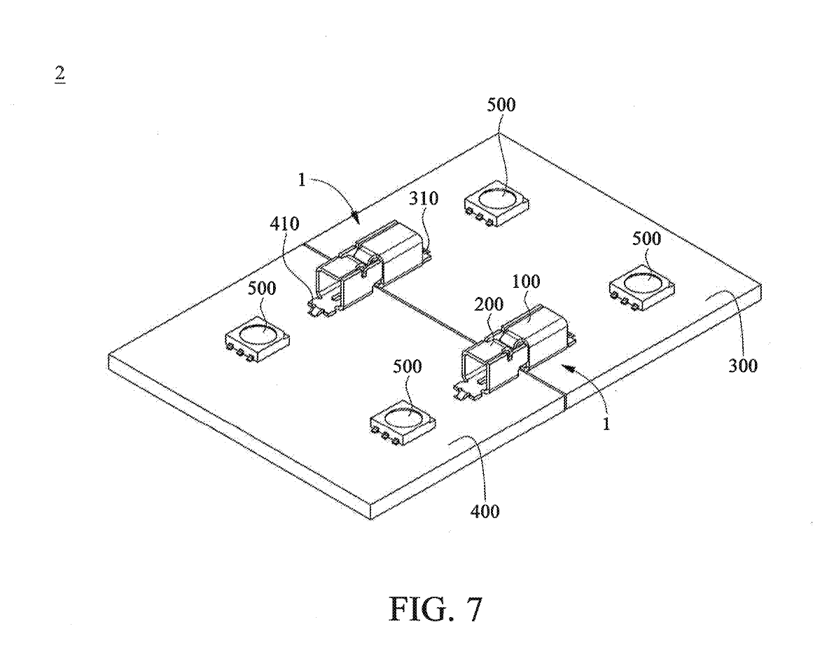

Referring to FIG. 7, there is shown a schematic perspective view of an LED module 2 according to the second embodiment of the present invention. When it comes to the LED module 2, the conductive connector 1 in the first embodiment is applied to the second embodiment of the present invention. The LED module 2 comprises the conductive connector 1, the first circuit board 300, and the second circuit board 400 in the first embodiment of the present invention. The first circuit board 300 has therein at least one LED component 500. The conductive connection plug 100 is disposed on the first circuit board 300 and positioned proximate to an edge of the first circuit board 300. The conductive connection plug 100 is soldered to a contact on the first circuit board 300. The second circuit board 400 has thereon the at least one LED component 500. The conductive connection socket 200 is disposed on the second circuit board 400 and positioned proximate to an edge of the second circuit board 400. The conductive connection socket 200 is soldered to a contact on the second circuit board 400. The conductive connection plug 100 can be plugged into the conductive connection socket 200 to thereby put together the first circuit board 300 and the second circuit board 400, thereby finalizing the assembly of the LED module 2. Accordingly, the LED module 2 in this embodiment has the following advantages: easy and convenient to assemble, easy to take apart, and easy to change a damaged circuit board. When in use, if the at least one LED component 500 on one of the first circuit board 300 and the second circuit board 400 gets damaged, only the at least one LED component 500 on the affected circuit board (i.e., either the first circuit board 300 or the second circuit board 400) will need to be changed; hence, in this situation, it is not necessary to discard the LED module 2 to the detriment of resource saving.

In the second embodiment of the present invention, the LED module 2 is exemplified by two circuit boards (the first circuit board 300 and the second circuit board 400), but the present invention is not limited thereto. In practice, the LED module 2 comprises at least two circuit boards which are connected in series by means of every two adjacent circuit boards, wherein the every two adjacent circuit boards is equipped with the conductive connection plug 100 and the conductive connection socket 200 which operate jointly. Furthermore, this embodiment and the accompanying drawings of the present invention are illustrative rather than restrictive of the quantity of the conductive connector 1. Hence, it is feasible that the quantity of the conductive connector 1 correlates with the circuit design of the two circuit boards and the quantity of the contacts thereon.

Hence, in the first embodiment of the present invention, a conductive connector for use with circuit boards is characterized in that two circuit boards are connected by a conductive connection plug and a conductive connection socket which are disposed on the two circuit boards, respectively, and operate in conjunction with each other, such that the conductive connection plug can be plugged into the conductive connection socket to thereby render assembly of the two circuit boards convenient and quick, and reduce required space. Furthermore, the conductive connector is simple in structure to thereby reduce the required use of materials and cut assembly costs. Furthermore, in the second embodiment of the present invention, an LED module is characterized in that circuit boards each having thereon at least one LED component are connected by means of a conductive connector, such that it is convenient and quick to put together the circuit boards and thereby render it easy to take apart the circuit boards and change a damaged one of the circuit boards.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A conductive connector adapted for use with circuit boards and adapted to electrically connect and series-connect a first circuit board and a second circuit board, the first circuit board having a first positioning point, and the second circuit board having a second positioning point, the conductive connector comprising:
a conductive connection plug having a first positioning portion, a first abutting portion, and an inserting portion, the first positioning portion being positioned at the first positioning point of the first circuit board, the first abutting portion being disposed at a bottom of the conductive connection plug and soldered to the first circuit board to abut thereon, wherein, as soon as the conductive connection plug is mounted on the first circuit board, the inserting portion protrudes from the first circuit board; and
a conductive connection socket having a second positioning portion, a second abutting portion, and a damping portion, the second positioning portion being positioned at the second positioning point of the second circuit board, the second abutting portion being disposed at a bottom of the conductive connection socket and soldered to the second circuit board to abut thereon, wherein, as soon as the conductive connection socket is mounted on the second circuit board, the clamping portion is positioned proximate to an edge of the second circuit board to thereby clamp the inserting portion of the conductive connection plug.

2. The conductive connector of claim 1, wherein the inserting portion of the conductive connection plug comprises an inserting plate and an engaging block protruding from a surface of the inserting plate, and the clamping portion of the conductive connection socket comprises a resilient clamping element, a stopping element, and an engaging hole disposed on the stopping element and corresponding in position to the engaging block, such that the resilient clamping element and the stopping element have therebetween a gap for admitting the inserting plate.

3. The conductive connector of claim 2, wherein the conductive connection socket further comprises two lateral baffling plates between which the clamping portion is disposed.

4. The conductive connector of claim 3, wherein the conductive connection plug has a first flat top connected to the inserting plate extending downward, the conductive connection socket has a second flat top connected to the resilient clamping element extending downward, and the stopping element connects to the second abutting portion and extends upward.

5. The conductive connector of claim 1, wherein, as soon as the conductive connection plug is plugged into the conductive connection socket, the first flat top of the conductive connection plug and the second flat top of the conductive connection socket are coplanar.

6. The conductive connector of claim 2, wherein, as soon as the conductive connection plug is plugged into the conductive connection socket, the first flat top of the conductive connection plug and the second flat top of the conductive connection socket are coplanar.

7. The conductive connector of claim 3, wherein, as soon as the conductive connection plug is plugged into the conductive connection socket, the first flat top of the conductive connection plug and the second flat top of the conductive connection socket are coplanar.

8. The conductive connector of claim 4, wherein, as soon as the conductive connection plug is plugged into the conductive connection socket, the first flat top of the conductive connection plug and the second flat top of the conductive connection socket are coplanar.

9. An LED module comprising the conductive connector, the first circuit board, and the second circuit board of claim 1, the first circuit board having thereon at least one LED component, and the second circuit board having thereon at least one LED component.
